(19) United States
(12) Patent Application Publication
(10) Pub. No.: US 2003/0071570 A1
(43) Pub. Date: Apr. 17, 2003

(54) Display apparatus and method of manufacturing the same

(76) Inventors: Hitoshi Tamashiro, Kanagawa (JP); Yuichi Iwase, Kanagawa (JP)

Correspondence Address: ROBERT DEPKE, HOLLAND + KNIGHT, 55 W. MONROE, CHICAGO, IL, 60603, US

(21) Appl. No.: 10/262,925

(22) Filed: Oct. 2, 2002

(30) Foreign Application Priority Data
Oct. 3, 2001 (JP) JP2001-307027
Nov. 27, 2001 (JP) JP2001-360323

(51) Int. Cl. H01J 1/62; H01J 63/04; H01J 9/26; H01J 9/32

(52) U.S. Cl. 313/512; 313/495; 445/25

(57) ABSTRACT

In a display apparatus including light-emitting devices and driving electrodes therefor provided on a panel substrate so as to form a light-emitting region and electrode regions in the surroundings of the light-emitting region, the panel substrate and a sealing substrate opposed thereto being adhered to each other through a sealing resin for sealing the light-emitting region, a protective wall for shielding the light-emitting region and the electrode regions from each other is provided between the panel substrate and the sealing substrate, whereby the sealing resin present inside the light-emitting region is prevented from diffusing to the side of the electrode regions.

### BACKGROUND OF THE INVENTION

The present invention relates to a display apparatus including light-emitting devices arranged on a panel substrate, and a method of manufacturing the same.

In recent years, the system (hereinafter referred to as “organic EL display”) including organic electroluminescence devices (hereinafter referred to as (“organic EL devices”) as light-emitting devices has been paid attention to as a planar type display apparatus. The organic EL display is a self-light-emitting type flat panel display which does not require a backlight, and has the merit that a display with a wide angle of visibility peculiar to the self-light-emitting type can be realized. In addition, since it suffices to turn ON only the required pixels, the organic EL display is advantageous to the backlight type (liquid crystal display or the like) with respect to power consumption. Besides, the organic EL display is considered to have sufficient performance of response to high-definition high-speed video signals of which practical use in the future is now expected.

In general, the organic EL device used for the organic EL display has a structure in which an organic material is clamped between electrodes (an anode and a cathode) from the upper and lower sides thereof. Positive holes from the anode and electrons from the cathode are respectively injected into an organic layer composed of the organic material, and the positive holes and the electrons are re-coupled with each other in the organic layer, resulting in emission of light. At this time, the organic EL device can provide a luminance of from several hundreds to several tens of thousands of cd/m² under a driving voltage of not more than 10 V. In addition, by appropriate selection of the organic material (fluorescent material), emission of light in desired colors can be achieved. Accordingly, the organic EL device is deemed as very promising as a light-emitting device for constituting a multicolor or full-color display apparatus.

In the organic EL device, however, if the organic layer is crystallized due to penetration of moisture or oxygen or the like causes, there would occur generation of a non-light-emitting spot called “dark spot”. It is known that the dark spot grows with time, and the growth of the dark spot shortens the life of the organic EL device. Therefore, in composing the organic EL display, it is necessary to restrain as securely as possible the penetration of moisture or oxygen into the organic EL devices or the like causes.

In view of this, some of the organic EL displays have a structure in which, as for example shown in FIG. 2, a display region on a panel substrate 1 where the organic displays are provided is covered with a sealing resin 2, and a sealing substrate 3 consisting of a glass plate or the like opposed to the panel substrate 1 is adhered to the panel substrate 1 in the manner of sandwiching the sealing resin 2 therebetween, so as thereby to seal the organic EL devices. In the organic EL display having such a constitution, for example, a UV-curable type or thermosetting type resin is used as the sealing resin 2, which is generally cured after adhesion of the sealing substrate 3. Since external electrodes 4 and external terminals 5 arranged in the surroundings of the display region are not sealed with the sealing resin 2 or the like, after the sealing of the organic EL devices a driving voltage is impressed on the organic EL devices through the external electrodes 4 and the external terminals 5, whereby the organic EL devices are driven.

However, in the process of manufacturing the above-mentioned conventional organic EL display, there is the fear that the sealing resin 2 for sealing the organic EL devices may flow out in an uncured state to the side of the external electrodes 4, thereby contaminating the external electrodes 4. If such a contamination occurs, it is difficult to secure electrical conduction in the external electrodes 4 and the external terminals 5, possibly resulting in a serious defect that the organic EL devices cannot be driven.

Particularly, in the process of manufacturing the organic EL display, in order to enhance productivity, the so-called multiple-product process is often adopted in which a plurality of organic EL displays 6 can be manufactured from a single sheet of large panel substrate 1, as for example shown in FIG. 3A. In this case, it is considered that the sealing substrate 3 large in size similarly to the panel substrate 1 is also used, as for example shown in FIG. 3B. Namely, the sealing resin 2 is applied correspondingly to a plurality of display regions formed on the panel substrate 1, the single large-sized sealing substrate 3 is adhered to the upper side of this, the individual portions of the sealing resin 2 is cured, and thereafter unnecessary portions of the sealing substrate 3 located between the display regions are removed. Therefore, in the case of the multiple-product process, it is highly possible that the adhesion of the large-sized panel substrate 1 and sealing substrate 3 to each other may be attended by a capillary phenomenon therebetween, and the uncured sealing resin 2 present therebetween may diffuse to the side of the external electrodes 4, as for example shown in FIG. 3C.

### SUMMARY OF THE INVENTION

It is an object of the present invention to provide a display apparatus and a method of manufacturing the same in which diffusion of a sealing resin to the side of external electrodes can be prevented while maintaining the function of the sealing resin for sealing organic EL devices, thereby contriving a higher quality and a higher yield of the display apparatus, and which are very effective particularly in the case of multiple-product process.

In order to attain the above object, in accordance with one aspect of the present invention, there is provided a display apparatus including light-emitting devices and driving electrodes therefor provided on a panel substrate so as to form a light-emitting region and an electrode region in the surroundings of the light-emitting region, the panel substrate and a sealing substrate opposed thereto being adhered to each other through a sealing resin for sealing the light-emitting region, wherein a protective wall for shielding the light-emitting region and the electrode region from each other is provided between the panel substrate and the sealing substrate.

Also, in order to attain the above object, in accordance with another aspect of the present invention, there is provided a method of manufacturing a display apparatus including light-emitting devices and driving electrodes therefor provided on a panel substrate so as to form a light-emitting region and an electrode region in the surroundings of the light-emitting region, the panel substrate and a sealing substrate opposed thereto being adhered to each other through a sealing resin for sealing the light-emitting region, wherein a protective wall projecting from the panel substrate toward the side of the sealing substrate or a protective wall projecting from the sealing substrate toward the side of the panel substrate is preliminarily provided at a position for shielding the light-emitting region and the electrode region from each other prior to adhesion of the sealing substrate.

According to the display apparatus and the method of manufacturing the same constituted as described above, the protective wall is provided between the panel substrate and the sealing substrate, so that the uncured sealing resin applied to the light-emitting region and tending to diffuse to the side of the electrode region due for example to capillary phenomenon at the time of adhesion of the sealing substrate is blocked by the protective wall. Namely, diffusion of the sealing resin to the side of the electrode region can be prevented by the protective wall shielding the light-emitting region and the electrode region from each other.

Therefore, it is possible to prevent the sealing resin from contaminating driving electrodes or the like in the electrode region, and it is possible to contrive a higher quality and a higher yield of the display apparatus. In addition, this is very effective particularly in the case of multiple-product process.

The above and other objects, features and advantages of the present invention will become apparent from the following description and appended claims, taken in conjunction with the accompanying drawings which show by way of example some preferred embodiments of the invention.

### BRIEF DESCRIPTION OF THE DRAWINGS

FIGS. 1A to 1C are illustrations of outline of organic EL displays and a method of manufacturing the same to which the present invention is applied, in which FIG. 1A is an illustration of an example of formation of protective walls, FIG. 1B is an illustration of the manner of adhering substrates, and FIG. 1C is an illustration of the condition of a sealing resin;

FIGS. 2A and 2B are illustrations of an example of constitution of a general organic EL display, in which FIG. 2A is a plan view, and FIG. 2B is a side view; and

FIGS. 3A to 3C are illustrations of outline of organic EL displays and a method of manufacturing the same in the case of multiple-product process, in which FIG. 3A is an illustration of an example of arrangement of the organic EL displays on a substrate, FIG. 3B is an illustration of the manner of adhering the substrates, and FIG. 3C is an illustration of the condition of a sealing resin.

### DESCRIPTION OF THE PREFERRED EMBODIMENTS

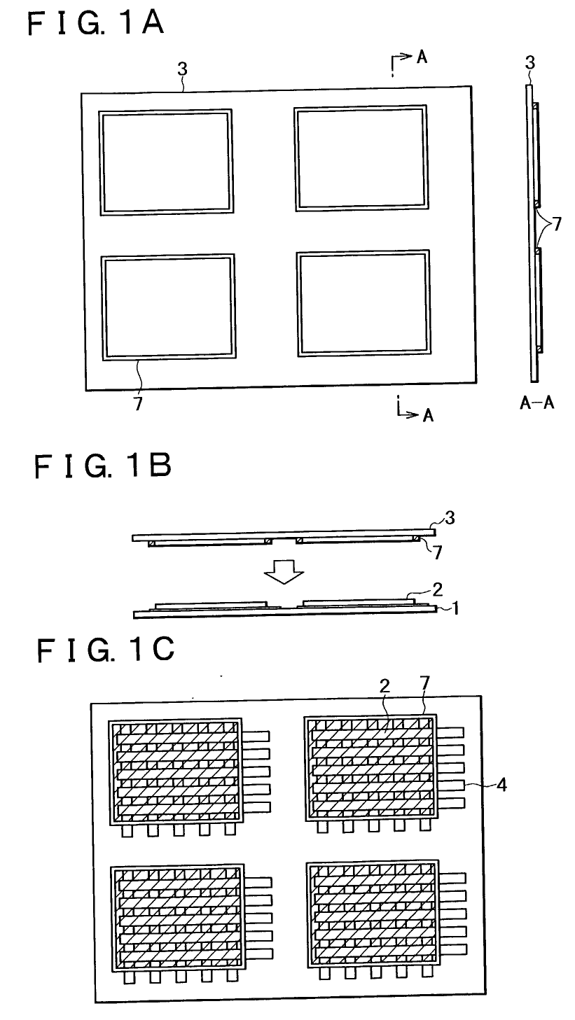

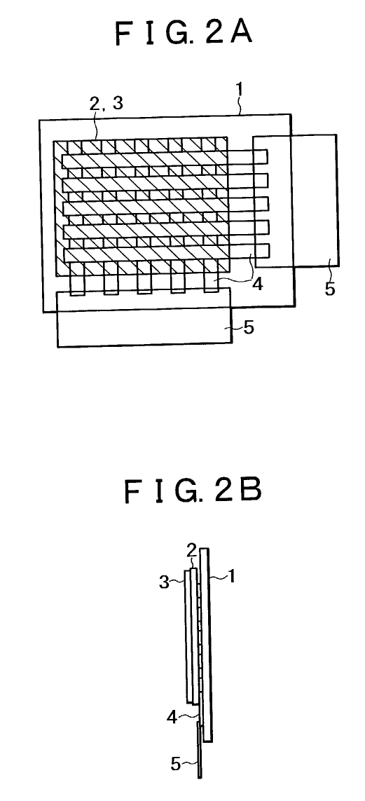

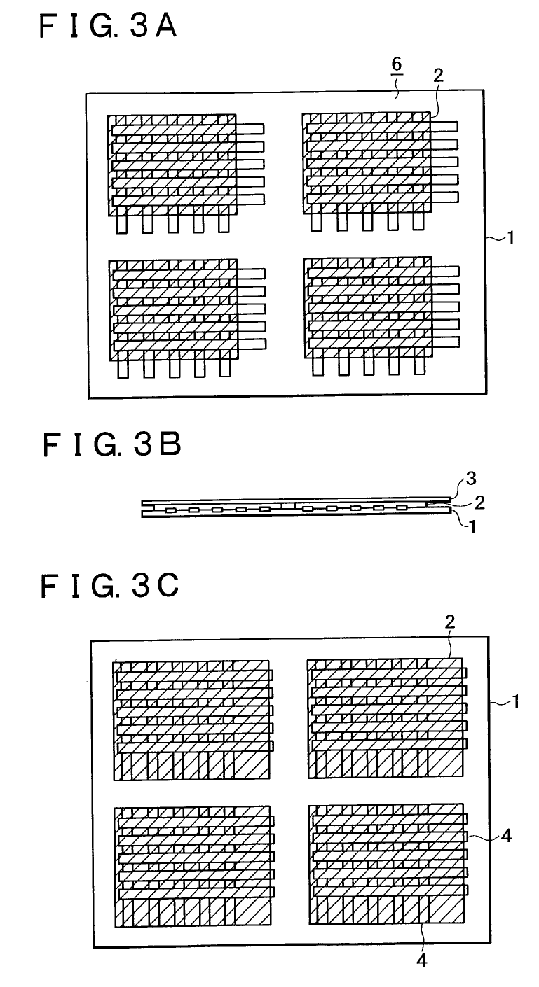

Now, the display apparatus and the method of manufacturing the same according to the present invention will be described below referring to the drawings. Here, the present invention will be described by taking as an example the case where the invention is applied to an organic EL display manufactured by multiple-product process. FIG. 1 shows illustrations of the outline of the organic EL displays and the method of manufacturing the same to which the present invention is applied. In the illustrations, the same component elements as those in the prior art (See FIGS. 2 and 3) are denoted by the same symbols as those used above.

As shown in the illustrations, the organic EL display according to this embodiment is characterized in that a protective wall 7 for shielding a light-emitting region and electrode regions located in the surroundings of the light-emitting region from each other is provided between a panel substrate 1 and a sealing substrate 3, singly so as to surround the light-emitting region.

Here, the procedure for manufacturing the organic EL display constituted as above, namely, the method of manufacturing the display apparatus according to the present invention will be described more in detail. At the time of manufacturing the above-mentioned organic EL display, first, as shown in FIG. 1A, rectangular frame-like protective walls 7 each surrounding entirely the light-emitting region are provided on the adherend surface side of the sealing substrate 3 correspondingly to the plurality of light-emitting regions arranged on the panel substrate 1. Therefore, in the case where, for example, four light-emitting regions are arranged on the panel substrate 1, the rectangular frame-like protective walls 7 are provided at four locations on the sealing substrate 3.

The protective walls 7 may be provided in a desired shape by, for example, adhering a thick dry film resist onto a surface of the sealing substrate 3, and then removing unnecessary portions of the dry film resist by a known photolithography method. In place of the dry film resist, a spin coating method may be used as far as a thick film can be formed. It may also be contemplated to use a thick film which is formed by any of various printing methods, such as screen printing and pad printing, or a dispensing method followed by smoothening.

The film thickness required for forming the protective walls 7 may be such that the film can be contained in the gap between the panel substrate 1 and the sealing substrate 3 at the time of composing the organic EL displays and that the flow-out of the uncured sealing resin 2 can be prevented. Specifically, the film thickness may be in the range of about 2 μm to about 0.5 mm. Namely, the height of the protective walls 7 is in the range of about 2 μm to about 0.5 mm. Also, the width of the protective walls 7 may be such that the flow-out of the uncured sealing resin 2 can be prevented. Specifically, the width may be in the range of about 2 μm to about 5 mm.

The material for forming the protective walls 7 is not necessarily limited to the dry film resist, but may be any material which is an insulating material and which shows an appropriate strength for preventing the uncured sealing resin 2 from flowing out.

By this, the protective walls 7 projecting from the sealing substrate 3 toward the side of the panel substrate 1 are provided on the adherend surface side of the sealing substrate 3, correspondingly to the individual light-emitting regions and at locations for shielding the light-emitting regions and the electrode regions in the surroundings thereof from each other.

After the formation of the protective walls 7, an appropriate amount of the sealing resin 2 for covering each of the light-emitting regions on the panel substrate 1 is applied in an uncured state to each light-emitting region by use of, for example, a dispenser, as shown in FIG. 1B. In the condition where the uncured sealing resin 2 has been thus applied correspondingly to each light-emitting region, the panel substrate 1 and the sealing substrate 3 are adjusted in position, and the sealing substrate 3 is adhered opposedly to the panel substrate 1 in the manner of sandwiching the sealing resin 2 therebetween.

At this time, a capillary phenomenon occurs between the panel substrate 1 and the sealing substrate 3, and the uncured sealing resin 2 tends to diffuse from inside the light-emitting regions to the side of the electrode regions. However, the rectangular frame-like protective walls 7 are projecting from the sealing substrate 3 toward the panel substrate 1 in the manner of surrounding each of the light-emitting regions. Therefore, the uncured sealing resin 2 tending to diffuse is blocked by the protective walls 7 between the light-emitting regions and the electrode regions, so that the sealing resin 2 would not flow out to the side of the electrode regions. Namely, even if the capillary phenomenon occurs between the panel substrate 1 and the sealing substrate 3, the uncured sealing resin 2 will remain inside the light-emitting regions, as shown in FIG. 1C.

Thereafter, such operations as curing the sealing resin 2 remaining inside the light-emitting regions by, for example, irradiation with UV rays and removal of unnecessary portions of the sealing substrate 3 located between the display regions are conducted. By this, a plurality of organic EL displays in each of which the protective wall 7 for shielding the light-emitting region and the electrode regions from each other is provided between the panel substrate 1 and the sealing substrate 3 are simultaneously obtained from the upper side of the single panel substrate 1.

As described above, according to the organic EL display and the method of manufacturing the same as described in the present embodiment, the light-emitting regions and the electrode regions are shielded from each other by the protective walls 7 provided between the panel substrate 1 and the sealing substrate 3, so that the uncured sealing resin 2 applied to each of the light-emitting regions is prevented from diffusing to the side of the electrode regions. Therefore, the sealing resin 2 can be prevented from contaminating the external electrode 4 or the like in the electrode regions, and, accordingly, it is possible to obviate the serious defect that electrical conduction cannot be secured and the organic EL devices cannot be driven.

Particularly, in the case of multiple-product process, as described in the present embodiment, diffusion of the sealing resin 2 would easily occur due to the capillary phenomenon; however, the diffusion is prevented by the protective walls 7, whereby it is possible to contrive a higher quality and a higher yield of the organic EL display 6. Namely, the present invention is very effective in the case of multiple-product process.

Besides, since the protective wall 7 is provided singly in the surroundings of each light-emitting region in the manner of surrounding the light-emitting region, it is possible to securely prevent the sealing resin 2 from diffusing to the side of the electrode regions. The protective wall 7 may not necessarily be provided singly, but may be provided, for example, doubly or more in the surroundings of each light-emitting region. Namely, it suffices that the protective wall 7 is provided at least singly. When the protective wall 7 is provided doubly or more, enhancement of the effect of preventing the diffusion of the sealing resin 2, a reduction in the size of the protective wall 7 per single piece, and the like effects can be expected.

While the case of multiple-product process has been taken as an example in the present embodiment, the present invention can be applied in quite the same manner to the case where the multiple-product process is not conducted. The same effects as above can be obtained even in the case where the multiple-product process is not conducted.

In addition, while the case where the protective walls 7 project from the sealing substrate 3 toward the side of the panel substrate 1 has been taken as an example in the present embodiment, conversely, a case where the protective walls 7 project from the panel substrate 1 toward the side of the sealing substrate 3 may also be contemplated. In this case, the formation of the protective walls 7 may be conducted at such a stage as not to impose inconveniences to the formation of the organic EL devices on the panel substrate 1, for example, at a stage after the formation of the organic EL devices. The formation of the protective walls 7 may be conducted by use of a dry film resist or the like, in the same manner as in the present embodiment described above.

In short, it suffices that the protective wall 7 for shielding the light-emitting region and the electrode regions from each other is located between the panel substrate 1 and the sealing substrate 3 when the organic EL display is composed by adhering the sealing substrate 3 opposedly to the panel substrate 1.

Furthermore, while the application of the present invention to an organic EL display which is a display apparatus including organic EL devices as light-emitting devices has been described in the present embodiment, the present invention is not limited to this application. The present invention can be applied also to a display apparatus which includes self-light-emitting type light-emitting devices such as, for example, inorganic electroluminescence devices.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A display apparatus comprising light-emitting devices and driving electrodes therefor provided on a panel substrate so as to form a light-emitting region and an electrode region in the surroundings of said light-emitting region, said panel substrate and a sealing substrate opposed thereto being adhered to each other through a sealing resin for sealing said light-emitting region, wherein
protective wall for shielding said light-emitting region and said electrode region from each other is provided between said panel substrate and said sealing substrate.

2. A display apparatus according to claim 1, wherein said protective wall is provided at least singly in the surroundings of said light-emitting region.

3. A display apparatus according to claim 1, wherein said protective wall is so-provided as to project from said panel substrate toward the side of said sealing substrate.

4. A display apparatus according to claim 1, wherein said protective wall is so provided as to project from said sealing substrate toward the side of said panel substrate.

5. A method of manufacturing a display apparatus comprising light-emitting devices and driving electrodes therefor provided on a panel substrate so as to form a light-emitting region and an electrode region in the surroundings of said light-emitting region, said panel substrate and a sealing substrate opposed thereto being adhered to each other through a sealing resin for sealing said light-emitting region, wherein
a protective wall projecting from said panel substrate toward the side of said sealing substrate is preliminarily provided at a location for shielding said light-emitting region and said electrode region from each other prior to adhesion of said sealing substrate.

6. A method of manufacturing a display apparatus according to claim 5, wherein said protective wall is provided at least singly in the surroundings of said light-emitting region.

7. A method of manufacturing a display apparatus comprising light-emitting devices and driving electrodes therefor provided on a panel substrate so as to form a light-emitting region and an electrode region in the surroundings of said light-emitting region, said panel substrate and a sealing substrate opposed thereto being adhered to each other through a sealing resin for sealing said light-emitting region, wherein
a protective wall projecting from said sealing substrate toward the side of said panel substrate is preliminarily provided at a location for shielding said light-emitting region and said electrode region from each other prior to adhesion of said sealing substrate.

8. A method of manufacturing a display apparatus according to claim 7, wherein said protective wall is provided at least singly in the surroundings of said light-emitting region.
